(19) United States
(12) Patent Application Publication
(10) Pub. No.: US 2025/0374802 A1
(43) Pub. Date: Dec. 4, 2025

(54) DISPLAY DEVICE

(71) Applicant: Samsung Display Co., LTD., Yongin-si (KR)

(72) Inventors: Ji Hye SHIN, Yongin-si (KR); So Jeong LA, Yongin-si (KR); Jai Ku SHIN, Yongin-si (KR); Gyeong Ho JEONG, Yongin-si (KR); Sung Chul CHOI, Yongin-si (KR)

(21) Appl. No.: 19/022,914

(22) Filed: Jan. 15, 2025

(30) Foreign Application Priority Data
May 30, 2024 (KR) 10-2024-0070944

(51) Int. Cl. H10K 59/80

(52) U.S. Cl. CPC H10K 59/873

(57) ABSTRACT

A display device according to some embodiments of the present disclosure includes: a display panel including a folding area and a non-folding area on one side of the folding area; a window composite layer on one surface of the display panel, including a window and a resin on the window; an upper protective film on the window composite layer; and a panel support layer on another surface of the display panel, wherein: the window includes a first portion that overlaps with the folding area, and a second portion on one side of the first portion; a thickness of the second portion is greater than a thickness of the first portion; and a thickness of the resin on the first portion is greater than a thickness of the resin on the second portion.

### CROSS-REFERENCE TO RELATED APPLICATION

The present application claims priority to and the benefit of Korean Patent Application No. 10-2024-0070944, filed on May 30, 2024, in the Korean Intellectual Property Office, the entire disclosure of which is incorporated herein by reference.

### BACKGROUND

### 1. Field

Aspects of embodiments of the present disclosure relate to a display device.

### 2. Description of the Related Art

With the advancement of the information age, the demand for a display device for displaying an image has increased with various forms. The display device may be a display device such as a liquid crystal display device, a field emission display device, and a light emitting display device. The light emitting display device may include an organic light emitting display device that includes an organic light emitting diode element as a light emitting element or an inorganic light emitting display device that includes an inorganic light emitting diode element as a light emitting element.

Recently, in order to increase the portability of the display device and, at the same time, provide a wide display screen, a bendable display device in which a display area may be bent or a foldable display device in which a display area may be folded has been launched.

The above information disclosed in this Background section is only for enhancement of understanding of the background of the invention and therefore it may contain information that does not form the prior art.

### SUMMARY

Aspects of the present disclosure are directed to a display device that reduces a thickness.

Some other aspects of the present disclosure are directed to a display device that reinforces impact resistance.

The aspects of the present disclosure are not limited to those mentioned above and additional aspects of the present disclosure, which are not mentioned herein, will be clearly understood by those skilled in the art from the following description of the present disclosure.

According to some embodiments of the present disclosure, there is provided a display device including: a display panel including a folding area and a non-folding area on one side of the folding area; a window composite layer on one surface of the display panel, including a window and a resin on the window; an upper protective film on the window composite layer; and a panel support layer on another surface of the display panel, wherein: the window includes a first portion that overlaps with the folding area, and a second portion on one side of the first portion; a thickness of the second portion is greater than a thickness of the first portion; and a thickness of the resin on the first portion is greater than a thickness of the resin on the second portion.

In some embodiments, the window may include a first surface and a second surface positioned to be opposite to the first surface, and the window may include a groove recessed toward the second surface on the first surface.

In some embodiments, the first surface may include a first sub-surface and a second sub-surface, which are positioned at different heights, and a third sub-surface positioned between the first sub-surface and the second sub-surface, the first sub-surface may be positioned on a bottom surface of the groove, the second sub-surface may be positioned at a portion of the first surface, in which the groove is not positioned, and the third sub-surface may be positioned on an inner side of the groove.

In some embodiments, each of the first sub-surface and the second sub-surface may be a flat surface.

In some embodiments, the third sub-surface may be an inclined surface or a vertical surface.

In some embodiments, the first surface may face the upper protective film, and the second surface may face the display panel.

In some embodiments, the resin may be between the upper protective film and the window.

In some embodiments, the second surface may face the upper protective film, and the first surface faces the display panel.

In some embodiments, the resin may be between the display panel and the window.

In some embodiments, the display panel may include a light emitting element layer and a touch sensor layer on the light emitting element layer, the touch sensor layer may include a plurality of first sensing electrodes and a plurality of second sensing electrodes, which are arranged in different directions and include a first electrode and a second electrode, respectively, and the second electrode may surround the first electrode.

In some embodiments, the touch sensor layer may include a plurality of first bridge electrodes electrically connecting the plurality of first sensing electrodes to each other and a plurality of second bridge electrodes electrically connecting the plurality of second sensing electrodes to each other, the first bridge electrodes may be insulated from the plurality of second sensing electrodes, and the second bridge electrodes may be insulated from the plurality of first sensing electrodes.

In some embodiments, the panel support layer may include a grid pattern in the folding area, including a plurality of bars and a plurality of slits between the plurality of bars, and a width of the plurality of bars may become narrower from a center toward an edge of the folding area.

In some embodiments, the panel support layer may include a lower functional layer including a magnetic metal powder.

In some embodiments, the panel support layer may include: a first layer including a first fiber extending in a first direction; a second layer on the first layer and containing a second fiber extending in a second direction different from the first direction; and a third layer on the second layer and containing the first fiber, and the lower functional layer further may include a first functional layer between the first layer and the second layer and a second functional layer between the second layer and the third layer.

In some embodiments, the display device may further include a lower functional layer on the panel support layer, and the lower functional layer may contain a magnetic metal powder.

According to some embodiments of the present disclosure, there is provided a display device including television including: a display device as described above; and a speaker configured to generate audio corresponding to images displayed on the display device.

According to some embodiments of the present disclosure, there is provided a display device including smart phone including: a display device as described above; and a battery configured to store electrical energy and to power the display device.

According to some embodiments of the present disclosure, there is provided a display device including: a display panel including a folding area and a non-folding area on one side of the folding area and further including a light emitting element layer and a touch sensor layer on the light emitting element layer, the touch sensor layer including a digitizer; a window on one surface of the display panel, having a constant thickness; an upper protective film on the window; and a panel support layer on the other surface of the display panel, and including a lower functional layer containing a magnetic metal powder.

In some embodiments, the upper protective film may include a first support layer and a second support layer on the first support layer, and a modulus of elasticity of the second support layer may be smaller than a modulus of elasticity of the first support layer.

In some embodiments, the second support layer may be below the first support layer.

In some embodiments, the panel support layer may include: a first layer containing a first fiber extending in a first direction; a second layer on the first layer and containing a second fiber extending in a second direction different from the first direction; and a third layer on the second layer and containing the first fiber, and the lower functional layer further may include a first functional layer between the first layer and the second layer and a second functional layer between the second layer and the third layer.

In some embodiments, the touch sensor layer may include a first sensing electrode for recognizing an input of an input device and a second sensing electrode for recognizing an input by a user's touch.

The effects according to some embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating an unfolded state of a display device according to some embodiments of the present disclosure;

FIG. 2 is a perspective view illustrating a folded state of a display device according to some embodiments of the present disclosure;

FIG. 3 is a perspective view illustrating an unfolded state of a display device according to some other embodiments of the present disclosure;

FIG. 4 is a perspective view illustrating a folded state of a display device according to some other embodiments of the present disclosure;

FIG. 5 is a cross-sectional view illustrating a display device according to some embodiments of the present disclosure;

FIG. 6 is a cross-sectional view illustrating a window composite layer according to some embodiments of the present disclosure;

FIG. 7 is a cross-sectional view illustrating an example of a display panel according to some embodiments of the present disclosure;

FIG. 8 is a plan view illustrating an input sensor according to some embodiments of the present disclosure;

FIG. 9 is a view illustrating a sensing electrode according to some embodiments of the present disclosure;

FIG. 10 is a view illustrating an operation of a display device according to some embodiments of the present disclosure in a first frame;

FIG. 11 is a view illustrating an operation of a display device according to some embodiments of the present disclosure in a second frame;

FIG. 12 is a cross-sectional view illustrating a panel support layer according to some embodiments of the present disclosure;

FIG. 13 is a cross-sectional view illustrating a stacked structure of a panel support layer according to some embodiments of the present disclosure;

FIG. 14 is a perspective view illustrating a panel support layer according to some embodiments of the present disclosure;

FIG. 15 is a cross-sectional view illustrating a display device according to some other embodiments of the present disclosure;

FIG. 16 is a cross-sectional view illustrating a display device according to some other embodiments of the present disclosure;

FIG. 17 is a cross-sectional view illustrating a display device according to some other embodiments of the present disclosure; and

FIG. 18 is a cross-sectional view illustrating a display device according to some other embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

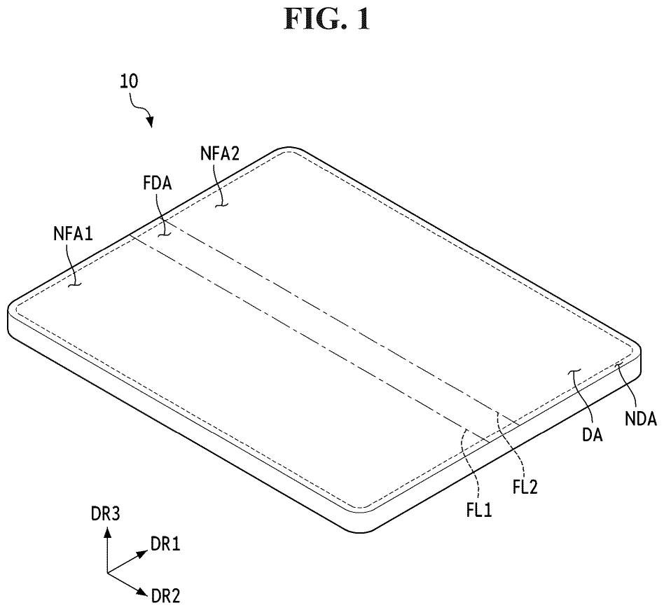

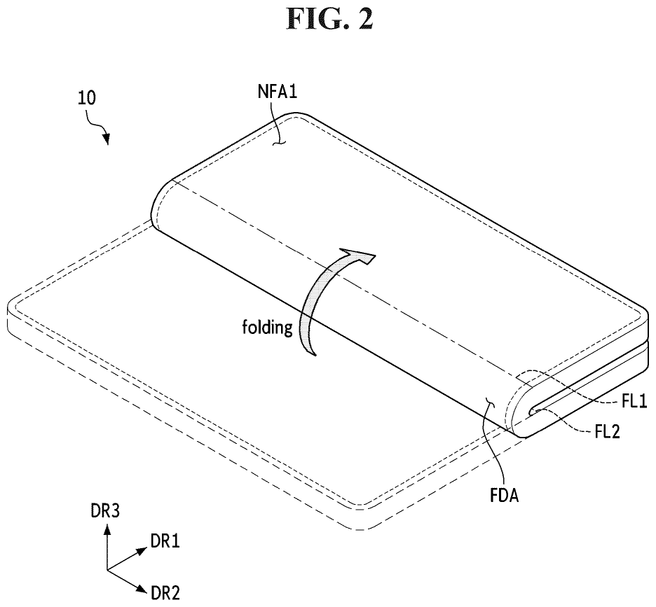

FIG. 1 is a perspective view illustrating an unfolded state of a display device according to some embodiments of the present disclosure. FIG. 2 is a perspective view illustrating a folded state of a display device according to some embodiments of the present disclosure.

Referring to FIGS. 1 and 2, a first state of a display device 10 unfolded

without folding in folding lines FL1 and FL2, and FIG. 2 is illustrated in FIG. 1, and a second state of the display device 10 folded in the folding lines FL1 and FL2 is illustrated in FIG. 2.

The display device 10 according to some embodiments may be a foldable display device. The display device 10 will be described based on that it is applied to (e.g., based on its application in) a smart phone but is not limited thereto. For example, the display device 10 according to some embodiments of the present disclosure is a device that displays a moving image or a still image, and may be used as a display screen of various products, such as a television, a laptop computer, a monitor, an advertising board, a device for Internet of things (IoT), and/or the like, as well as portable electronic devices, such as a mobile phone, a smart phone, a tablet personal computer (PC), a smart watch, a watch phone, a mobile communication terminal, an electronic diary, an electronic book, a portable multimedia player (PMP), a navigator, an ultra mobile PC (UMPC), and/or the like. A system, such as a smart phone, a television, a laptop computer, a monitor, an advertising board, a device for IoT, or the like, that utilizes the display device 10 according to some embodiments may further include a number of other components, such as a power supply for supplying power to various components of the system, a battery for storing electrical energy and powering the system (e.g., the display device 10) to enable it to operate without being directly plugged into a power source, a case for housing the various components of the system and to provide protection against physical damage, an antenna for enabling wireless communication with external devices, a speaker for generating audio corresponding to images displayed on the display panel, and/or the like.

The display device 10 according to some embodiments may be categorized variously in a suitable manner depending on a display method. For example, the display device 10 may include an organic light emitting display device, an inorganic light emitting display device, a quantum dot light emitting display device, a micro-LED display device, a nano-LED display device, a field emission display device, an electrophoretic display device, and/or the like. Hereinafter, the organic light emitting display device will be described as the display device by way of example, and the organic light emitting display device applied to some embodiments will simply be abbreviated (e.g., referred to) as the display device unless it is desired to be specially classified. However, some embodiments are not limited to the organic light emitting display device, and another display device listed as above or known in this art may be applied to some embodiments within the range of technical spirits of the present disclosure.

In the drawing, a first direction DR1 is a direction parallel with one side of the display device 10 when viewed on a plane, and may be, for example, a horizontal direction of the display device 10. A second direction DR2 is a direction parallel with the other side that is in contact with one side of the display device 10 when viewed on a plane, and may be, for example, a vertical direction of the display device 10. A third direction DR3 may be a thickness direction of the display device 10.

The first direction DR1 and the second direction DR2 may be horizontal directions and may cross each other. For example, the first direction DR1 and the second direction DR2 may be orthogonal to each other. Also, the third direction DR3 crosses the first and second directions DR1 and DR2, and may be, for example, a vertical direction orthogonal thereto. Unless defined otherwise, in the present disclosure, directions indicated by arrows in the first to third directions DR1, DR2, and DR3 may be referred to as one side, and their opposite directions may be referred to as the other side. Also, in the present disclosure, “upper”, “upper side”, “upper portion”, and “top” may refer to a direction toward which the arrow in the third direction DR3 is directed based on the drawing, and “lower”, “lower side”, “lower portion”, and “bottom” may refer to an opposite direction of the direction toward which the arrow in the third direction DR3 is directed based on the drawing.

The display device 10 may have a rectangular shape or a square shape when viewed on a plane, but is not limited thereto. In some embodiments, the display device 10 may have a rectangular shape with vertical corners or rounded corners when viewed on a plane. The display device 10 may include two short sides disposed in the first direction DR1 and two long sides disposed in the second direction DR2 when viewed on a plane.

The display device 10 may include a display area DA and a non-display area NDA. A shape of the display area DA may correspond to that of the display device 10 when viewed on a plane. For example, when the display device 10 has a rectangular shape when viewed on a plane, the display area DA may also have a rectangular shape.

The display area DA may be an area that includes a plurality of pixels to display an image. The plurality of pixels may be arranged in a matrix (e.g., grid) direction (e.g., formation or arrangement). The plurality of pixels may have a rectangular shape, a rhombus shape or a square shape when viewed on a plane, but are not limited thereto. For example, when viewed on a plane, the plurality of pixels may have another quadrangular shape rather than the rectangular shape, the rhombus shape, or the square shape, or the plurality of pixels may have another polygonal shape rather than the quadrangle, a circular shape or an oval shape.

The non-display area NDA may be an area that does not include pixels and thus does not display an image. The non-display area NDA may be disposed in the vicinity of the display area DA. The non-display area NDA may be disposed to surround (e.g., be around) the display area DA as shown in FIGS. 1 and 2, but is not limited thereto. The display area DA may be partially surrounded by the non-display area NDA.

The display device 10 may maintain both the first state that is an unfolded state and the second state that is a folded state. The display device 10 may be folded in an in-folding manner in which the display areas DA are disposed inside to face each other as shown in FIG. 2. When the display device 10 is folded in an in-folding manner, front surfaces of the display device 10 may face each other (e.g., facing toward each other). For example, the display device 10 may be folded in an out-folding manner in which the display areas DA are disposed outside to be opposite to each other (e.g., facing away from each other). When the display device 10 is folded in an out-folding manner, rear surfaces of the display device 10 may face each other.

The display device 10 may include a folding area FDA, a first non-folding area NFA1, and a second non-folding area NFA2. The folding area FDA may be an area in which the display device 10 is bent or folded, and the first non-folding area NFA1 and the second non-folding area NFA2 may be areas in which the display device 10 is neither bent nor folded. In some embodiments, the first non-folding area NFA1 and the second non-folding area NFA2 may be flat areas of the display device 10, but are not limited thereto.

The first non-folding area NFA1 may be disposed on one side of the folding area FDA, for example, a left side of the folding area FDA. The second non-folding area NFA2 may be disposed on another side of the folding area FDA, for example, a right side of the folding area FDA. For example, the left side may mean the other side in the first direction DR1, and the right side may mean one side in the first direction DR1.

The folding area FDA may be an area defined by a first folding line FL1 and a second folding line FL2, and may be an area in which the display device 10 is bent at a predetermined curvature. The first folding line FL1 may be a boundary between the folding area FDA and the first non-folding area NFA1, and the second folding line FL2 may be a boundary between the folding area FDA and the second non-folding area NFA2.

As shown in FIGS. 1 and 2, the first folding line FL1 and the second folding line FL2 may be extended in the second direction DR2, and in this case, the display device 10 may be folded along the first direction DR1. In some embodiments, when the display device 10 is in the folded state a length of the display device 10 in the first direction DR1 may be reduced by a half, approximately, such that a user may conveniently carry the display device 10.

When the first folding line FL1 and the second folding line FL2 are extended in the second direction DR2, a length of the folding area FDA in the second direction DR2 may be longer than a length of the folding area FDA in the first direction DR1. Also, a length of the first non-folding area NFA1 in the second direction DR2 may be longer than a length of the first non-folding area NFA1 in the first direction DR1. A length of the second non-folding area NFA2 in the second direction DR2 may be longer than a length of the second non-folding area NFA2 in the first direction DR1.

Each of the display area DA and the non-display area NDA may overlap (e.g., overlap with) at least one of the folding area FDA, the first non-folding area NFA1, or the second non-folding area NFA2. In FIGS. 1 and 2, each of the display area DA and the non-display area NDA is illustrated as overlapping with the folding area FDA, the first non-folding area NFA1 and the second non-folding area NFA2.

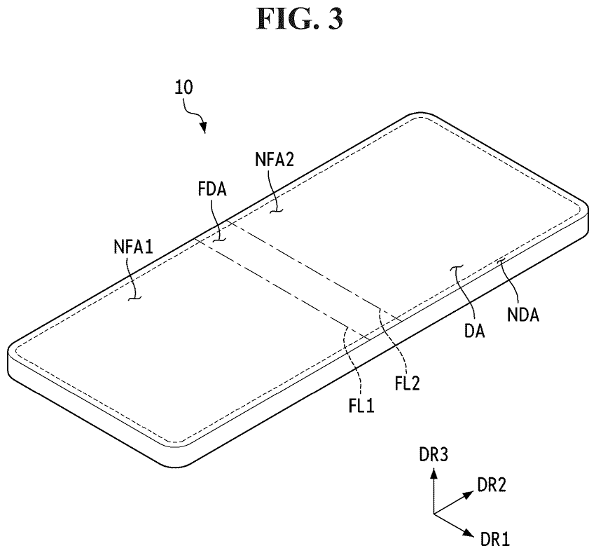

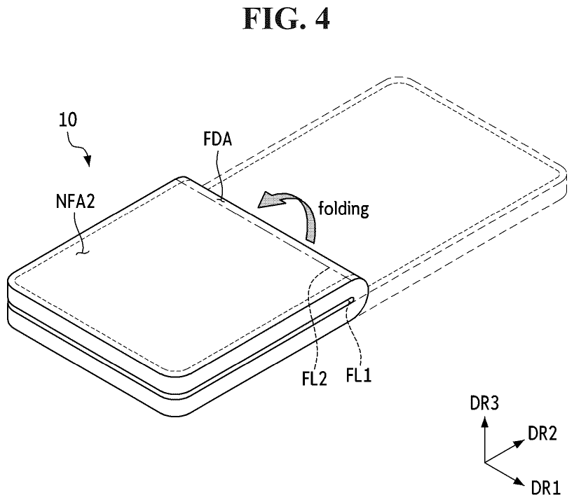

FIG. 3 is a perspective view illustrating an unfolded state of a display device according to some other embodiments of the present disclosure. FIG. 4 is a perspective view illustrating a folded state of a display device according to some other embodiments of the present disclosure.

Referring to FIGS. 3 and 4, the first state of the display device 10 unfolded without folding in (e.g., folding at) the folding lines FL1 and FL2 is shown in FIG. 3, and the second state of the display device 10 folded in (e.g., folded at) the folding lines FL1 and FL2 is shown in FIG. 2.

In some embodiments, in the first state in which the display device 10 is unfolded, a long side of the display device 10 may be extended along the second direction DR2, and a short side of the display device 10 may be extended along the first direction DR1.

In the display device 10 according to some embodiments shown in FIGS. 3 and 4, the first folding line FL1 and the second folding line FL2 may be extended in the first direction DR1, and the display device 10 may be folded along the second direction DR2.

The first non-folding area NFA1 may be disposed on one side of the folding area FDA, for example, a lower side thereof. The second non-folding area NFA2 may be disposed on another side of the folding area FDA, for example, an upper side thereof. For example, the upper side may mean the other side in the second direction DR2, and the lower side may mean one side in the second direction DR2.

As shown in FIGS. 3 and 4, when the first folding line FL1 and the second folding line FL2 are extended in the first direction DR1, a length of the folding area FDA in the first direction DR1 may be longer than a length of the folding area FDA in the second direction DR2. Also, a length of the first non-folding area NFA1 in the second direction DR2 may be longer than a length of the first non-folding area NFA1 in the first direction DR1. A length of the second non-folding area NFA2 in the second direction DR2 may be longer than a length of the second non-folding area NFA2 in the first direction DR1.

Hereinafter, for convenience of description, some embodiments of FIGS. 1 and 2 will be described by way of example, but the present disclosure is not limited thereto, and the following description may be equally applied to the embodiments of FIGS. 3 and 4.

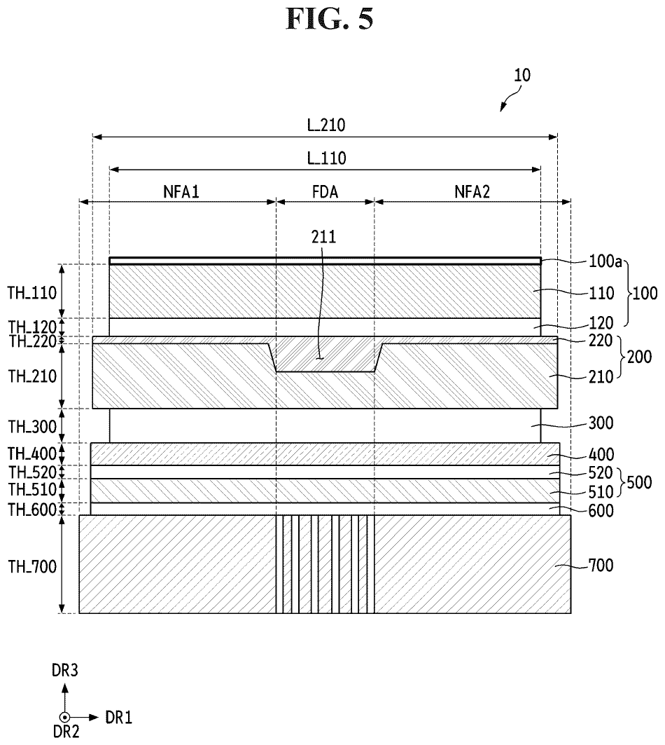

FIG. 5 is a cross-sectional view illustrating a display device according to some embodiments of the present disclosure.

Referring to FIG. 5, the display device 10 according to some embodiments of the present disclosure may include an upper protective film 100, a window composite layer 200, a second adhesive layer 300, a display panel 400, a lower protective film 500, a fourth adhesive layer 600 and a panel support layer 700.

The display panel 400 may be a panel for displaying an image. The display panel 400 may be an organic light emitting display panel including an organic light emitting layer, a quantum dot light emitting display panel including a quantum dot light emitting layer, an inorganic light emitting display panel using an inorganic semiconductor element as a light emitting element, a micro light emitting display panel using a micro light emitting diode as a light emitting element, and/or the like. Hereinafter, the following description will be based on that the display panel 400 is an organic light emitting display panel, but the present disclosure is not limited thereto. In some embodiments, a thickness TH_400 of the display panel 400 may be about 20 μm to about 40 μm, approximately. For example, the thickness TH_400 of the display panel 400 may be 30 μm, approximately.

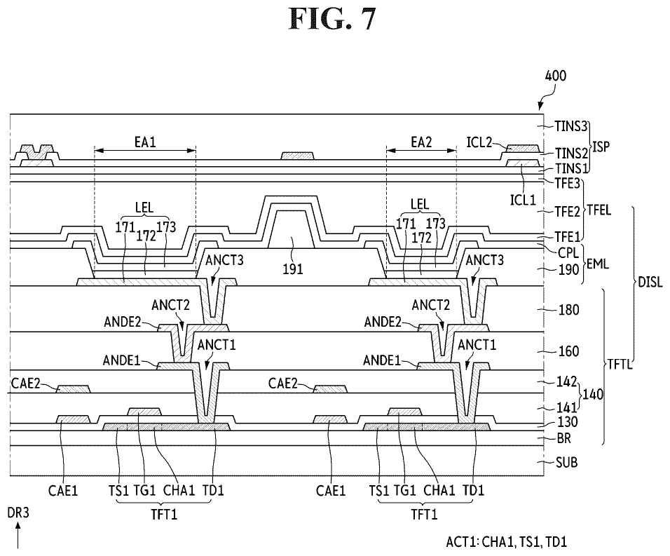

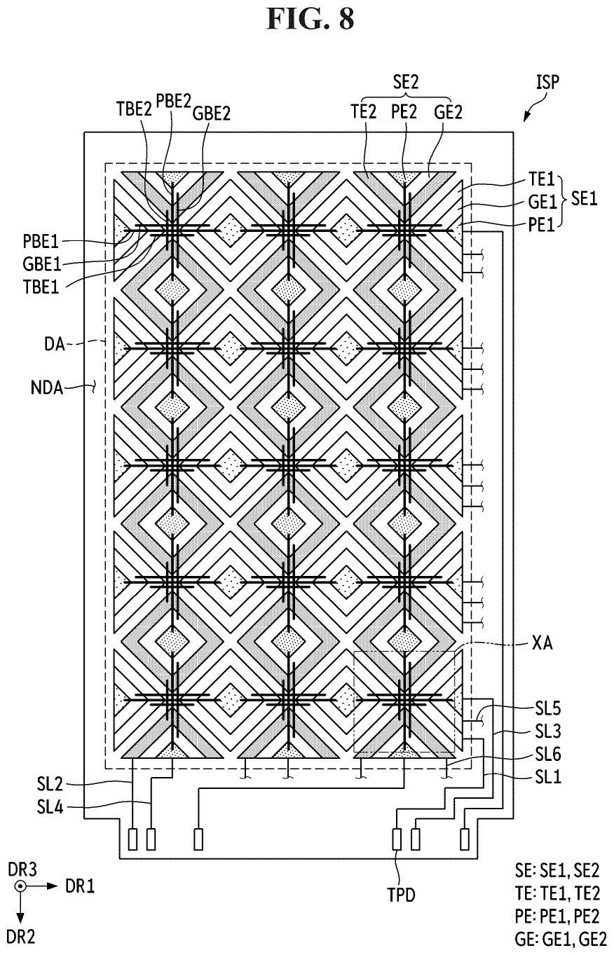

In some embodiments, the display panel 400 of the display device 10 may include a digitizer-embedded touch sensor layer ISP (see FIG. 7). For example, the touch sensor layer ISP (see FIG. 7) of the display panel 400 may not only recognize an input by a user's touch (e.g., an input by a touch using a portion of a body) but also recognize an input of an input device, such as a pen (e.g., an input using an electromagnetic interaction), due to the digitizer embedded therein. The touch sensor layer ISP will be described later with reference to FIG. 8.

The window composite layer 200 may be disposed on one surface of the display panel 400. For example, the window composite layer 200 may be disposed on an upper surface of the display panel 400. The window composite layer 200 may include a window 210 and a resin 220.

The window 210 may protect the display panel 400 from an external impact. The window 210 may enhance impact resistance of the display device 10. For example, the touch sensor layer ISP (see FIG. 7) of the display panel 400 on which the digitizer is packaged may be positioned above the display device 10 and thus may be relatively vulnerable to an external impact, and the window 210 may protect the touch sensor layer ISP (see FIG. 7) of the display panel 400.

The window 210 may be made of a transparent material. For example, the window 210 may be glass or plastic. In some embodiments, the window 210 may be ultra-thin glass (UTG) having a thickness of about 0.1 mm or less. For example, the window 210 may be a transparent polyimide film. In some embodiments, a thickness TH_210 of the window 210 may be about 70 μm to about 110 μm, approximately. For example, the thickness TH_210 of the window 210 may be 90 μm, approximately.

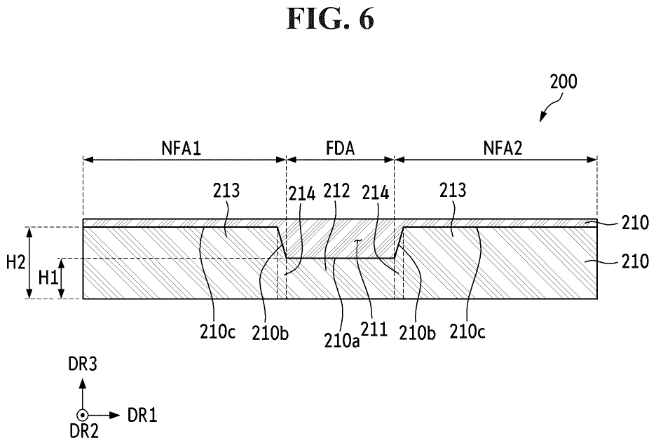

In some embodiments, the window 210 of the display device 10 may include a groove 211 disposed in the folding area FDA. Therefore, stress applied to the folding area FDA during folding of the display device 10 may be minimized or substantially reduced. A structure and the groove 211 of the window 210 will be described later with reference to FIG. 6.

The resin 220 may be disposed on the window 210. For example, the resin 220 may be disposed between the window 210 and the upper protective film 100. The resin 220 may planarize a step difference formed by the groove 211 of the window 210. The resin 220 may include at least one of an ultraviolet curing resin, a thermal curing resin or a natural curing resin.

In some embodiments, a thickness TH_220 of the resin 220 may be about 5 um to about 15 μm, approximately. For example, the thickness TH_220 of the resin 220 may be 10 μm, approximately. For example, the thickness TH_220 of the resin 220 may exclude a thickness of a portion disposed inside the groove 211 of the window 210, and may refer to the thickness TH_220 of the resin 220 disposed on an upper surface of the window 210 in which the groove 211 is not disposed.

In some embodiments, the resin 220 may cover the upper surface of the window 210. The resin 220 may prevent scattering of the window 210. For example, a length L_210 (or a size) of the window 210 may be greater than or equal to a length L_110 (or a size) of the upper protective layer 110. Therefore, a side end of the window 210 may be more protruded than a side end of the upper protective layer 110. The resin 220 may prevent scattering of the window 210 by covering a portion of the window 210, in which the window 210 does not overlap the upper protective layer 110 (or is more protruded than the upper protective layer 110).

The second adhesive layer 300 may be disposed below the window composite layer 200. For example, the second adhesive layer 300 may be disposed between the window composite layer 200 and the display panel 400. The window composite layer 200 and the display panel 400 may be coupled to each other through the second adhesive layer 300. The second adhesive layer 300 may include a transparent adhesive, such as a pressure sensitive adhesive (PSA) or an optically clear adhesive (OCA). For example, the second adhesive layer 300 may include an acrylic adhesive material. In some embodiments, a thickness TH_300 of the second adhesive layer 300 may be about 40 μm to about 60 μm, approximately. For example, the thickness TH_300 of the second adhesive layer 300 may be 50 μm, approximately.

The upper protective film 100 may be disposed on the window composite layer 200. The upper protective film 100 may include an upper protective layer 110, a coating film 100a and a first adhesive layer 120.

The upper protective layer 110 may perform at least one function of shock absorption, anti-scratch, anti-fingerprinting, anti-glare, or anti-scattering of the window 210. The upper protective layer 110 may include a material that has high flexibility and is resistant to scratches. For example, the upper protective layer 110 may be a polymer film or a reinforced glass film, such as polyethylene terephthalate. In some embodiments, the thickness TH_110 of the upper protective layer 110 may be about 70 μm to about 90 μm, approximately. For example, the thickness TH_110 of the upper protective layer 110 may be 80 μm, approximately.

The coating film 100a may be disposed on the upper protective layer 110. For example, the coating film 100a may be disposed on an upper surface of the upper protective layer 110. The coating film 100a may be a low-reflection and anti-fingerprint (LRAF) coating film.

The first adhesive layer 120 may be disposed below the upper protective layer 110. For example, the first adhesive layer 120 may be disposed between the upper protective layer 110 and the window composite layer 200. The upper protective layer 110 and the window composite layer 200 may be coupled to each other through the first adhesive layer 120. The first adhesive layer 120 may include a transparent adhesive, such as a pressure sensitive adhesive (PSA) or an optically clear adhesive (OCA). For example, the first adhesive layer 120 may include an acrylic adhesive material. In some embodiments, the thickness TH_120 of the first adhesive layer 120 may be about 20 μm to about 30 μm, approximately. For example, the thickness TH_120 of the first adhesive layer 120 may be 25 μm, approximately.

The first adhesive layer 120 may be handled while being attached to the upper protective layer 110 during processes such as storage and transport of the upper protective film 100. Before the first adhesive layer 120 is attached to the window composite layer 200, a release film may be disposed on a lower surface of the first adhesive layer 120. The release film may be attached to the lower surface of the first adhesive layer 120 when the upper protective film 100 is handled, and then may be removed when the first adhesive layer 120 is attached to the window composite layer 200.

The lower protective film 500 may be disposed on another surface of the display panel 400. For example, the lower protective film 500 may be disposed on a lower surface of the display panel 400. The lower protective film 500 may include a lower protective layer 510 and a third adhesive layer 520.

The lower protective layer 510 may serve to support the display panel 400 and protect the other surface of the display panel 400. In some embodiments, the lower protective layer 510 may be plastic such as polyethylene terephthalate (PET) or polyimide. In some embodiments, a thickness TH_510 of the lower protective layer 510 may be about 30 μm to about 40 μm, approximately. For example, the thickness TH_510 of the lower protective layer 510 may be 35 μm, approximately.

The third adhesive layer 520 may be disposed on the lower protective layer 510. For example, the third adhesive layer 520 may be disposed between the lower protective layer 510 and the display panel 400. The lower protective layer 510 and the display panel 400 may be coupled to each other through the third adhesive layer 520. The third adhesive layer 520 may include a transparent adhesive, such as a pressure sensitive adhesive (PSA) or an optically clear adhesive (OCA). For example, the third adhesive layer 520 may include an acrylic adhesive material. In some embodiments, a thickness TH_520 of the third adhesive layer 520 may be about 15 μm to about 20 μm, approximately. For example, the thickness TH_520 of the third adhesive layer 520 may be 18 μm, approximately.

The third adhesive layer 520 may be handled while being attached to the lower protective layer 510 during processes such as storage and transport of the lower protective film 500. Before the third adhesive layer 520 is attached to the display panel 400, a release film may be disposed on an upper surface of the third adhesive layer 520. The release film may be attached to the upper surface of the third adhesive layer 520 when the lower protective film 500 is handled, and then may be removed when the third adhesive layer 520 is attached to the display panel 400.

The panel support layer 700 may be disposed below the lower protective film 500. The panel support layer 700 may be a rigid member of which shape or volume is not easily changed by an external pressure. Because the panel support layer 700 is disposed on the other surface of the display panel 400 and is a rigid member of which shape or volume is not easily changed by an external pressure, the panel support layer 700 may support the display panel 400.

In some embodiments, the panel support layer 700 may be a metal plate. For example, the panel support layer 700 may be a metal plate, and may be made of metal or a metal alloy. The panel support layer 700 may include copper (Cu), aluminum (Al), stainless steel (SUS) and/or their alloys, but is not limited thereto.

In some other embodiments, the panel support layer 700 may be a polymer containing a carbon fiber or a glass fiber. For example, because the panel support layer 700 is formed of a polymer containing a carbon fiber or a glass fiber, an electromagnetic signal of the digitizer member may pass through the panel support layer 700 when the display device 10 includes a digitizer member below the panel support layer 700. Therefore, the panel support layer 700 capable of supporting the display panel 400 without lowering touch sensitivity of the digitizer member may be provided.

The panel support layer 700 may include a grid pattern disposed in the folding area FDA so that it may be easily bent in the folding area FDA. In embodiments wherein the panel support layer 700 includes a grid pattern disposed in the folding area FDA, the panel support layer 700 may be bent by a relatively small force during folding of the display device 10.

In some embodiments, the panel support layer 700 of the display device 10 may include an active control pattern as the grid pattern. Therefore, stress applied to the folding area FDA during folding of the display device 10 may be reduced, and occurrence of crease in the folding area FDA may be minimized or the likelihood of a crease forming in the folding area may be substantially reduced.

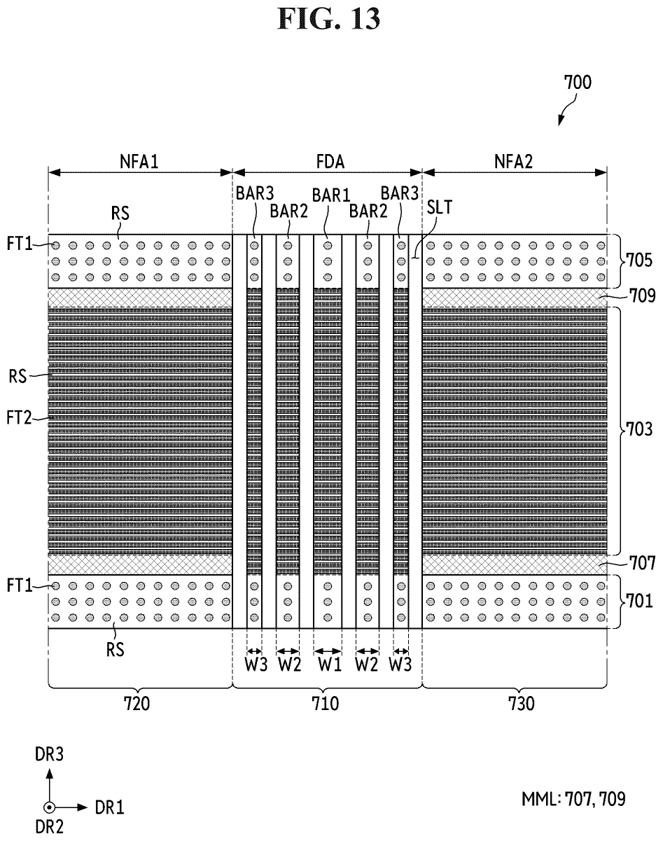

In some embodiments, the panel support layer 700 of the display device 10 according to the present embodiment may further include a lower functional layer MML (see, e.g., FIG. 13). Therefore, the thickness of the display device 10 may be reduced.

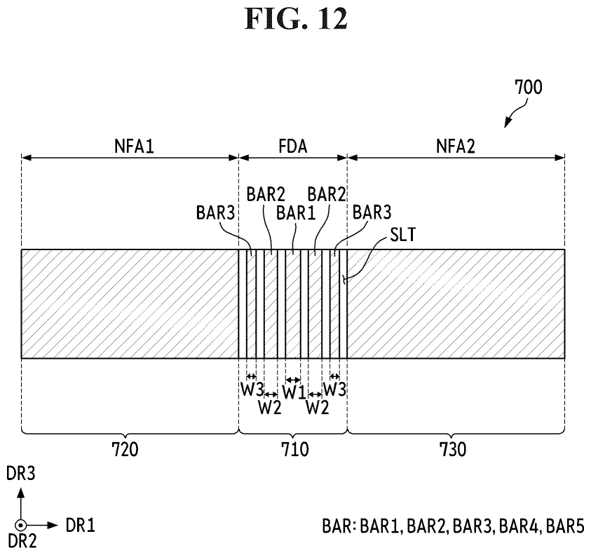

The active control pattern and the lower functional layer will be described later with reference to FIG. 12.

The fourth adhesive layer 600 may be disposed on the panel support layer 700. For example, the fourth adhesive layer 600 may be disposed between the panel support layer 700 and the lower protective film 500. The panel support layer 700 and the lower protective film 500 may be coupled to each other through the fourth adhesive layer 600. The fourth adhesive layer 600 may include a transparent adhesive, such as a pressure sensitive adhesive (PSA) or an optically clear adhesive (OCA). For example, the fourth adhesive layer 600 may include an acrylic adhesive material. In some embodiments, a thickness TH_600 of the fourth adhesive layer 600 may be about 14 μm to about 18 μm, approximately. For example, the thickness TH_600 of the fourth adhesive layer 600 may be 16 μm, approximately.

FIG. 6 is a cross-sectional view illustrating a window composite layer according to some embodiments of the present disclosure.

Referring to FIG. 6 in addition to FIG. 5, the window 210 may include a groove 211. The groove 211 may be a portion in which one surface (e.g., an upper surface) of the window 210 is recessed toward the other surface (e.g., a lower surface) at a portion that overlaps with the folding area FDA. The window 210 may include a step difference between the folding area FDA and the first non-folding area NFA1 and between the folding area FDA and the second non-folding area NFA2 by the groove 211.

One surface (e.g., an upper surface) of the window 210 may include a base surface 210a, an inner side 210b and a top surface 210c. The base surface 210a may be a bottom surface positioned inside the groove 211. The inner side 210b may be a side positioned inside the groove 211. The top surface 210c may be a portion of one surface of the window 210, in which the groove 211 is not disposed.

The inner side 210b is shown as a straight inclined surface in a cross-section, but is not limited thereto. For example, the inner side 210b may be a vertical surface extended in the third direction DR3. For another example, the inner side 210b may be a curved inclined surface in a cross-section.

In some embodiments, the base surface 210a may be disposed in the folding area FDA. For example, a width of the base surface 210a may be the same or substantially the same as a width of the folding area FDA. For example, the inner side 210b and the top surface 210c each may be disposed in the first non-folding area NFA1 and the second non-folding area NFA2.

However, the present disclosure is not limited to the above example. For example, the width of the base surface 210a may be greater than the width of the folding area FDA. For example, the base surface 210a may overlap with the folding area FDA, the first non-folding area NFA1, and the second non-folding area NFA2, and the inner side 210b and the top surface 210c each may be disposed in the first non-folding area NFA1 and the second non-folding area NFA2.

As another example, the width of the base surface 210a may be smaller than the width of the folding area FDA. In this case, the base surface 210a may overlap with only the folding area FDA, and each of the inner side 210b and the top surface 210c may overlap with the folding area FDA or not.

In some embodiments, each of the base surface 210a and the top surface 210c may be a flat surface.

The window 210 may include at least two portions having their respective thicknesses different from each other. The window 210 may be a hybrid thin glass (HTG) having different thicknesses in at least a portion thereof.

For example, the window 210 may include a first portion 212, a second portion 213 disposed on one side and the other side of the first portion 212, and a third portion 214 disposed between the first portion 212 and the second portion 213. The first portion 212 may be a portion that overlaps with the base surface 210a in the third direction DR3, the second portion 213 may be a portion that overlaps with the top surface 210c in the third direction DR3, and the third portion 214 may be a portion that overlaps with the inner side 210b in the third direction DR3.

A thickness H1 of the first portion 212 may be smaller than a thickness H2 of the second portion 213. The thickness H1 of the first portion 212 and the thickness H2 of the second portion 213 may be generally constant. For example, the thickness H1 of the first portion 212 may be about 30 μm to about 70 μm, approximately, and the thickness H2 of the second portion 213 may be about 70 μm to about 110 μm, approximately. For example, the thickness H1 of the first portion 212 may be 50 μm, approximately, and the thickness H2 of the second portion 213 may be 30 μm, approximately. A difference between the thickness H2 of the second portion 213 and the thickness H1 of the first portion 212 may be 20 μm or more, approximately.

Because the display device 10 according to the present embodiment includes a composite thin film glass, impact resistance may be enhanced. Therefore, because a separate upper protective layer is not required to be additionally disposed between the window composite layer 200 and the display panel 400, the thickness of the display device 10 may be reduced. For example, in some embodiments, in order to reduce the thickness of the display device 10, the window composite layer 200 may be directly disposed on the display panel 400 through the second adhesive layer 300, and no layer except the adhesive layer may be disposed between the window composite layer 200 and the display panel 400.

In addition, because the window 210 includes the groove 211, stress applied to the folding area FDA during folding of the display device 10 may be minimized or substantially reduced.

FIG. 7 is a cross-sectional view illustrating an example of a display panel according to some embodiments of the present disclosure.

Referring to FIG. 7, the display panel 400 may include a substrate SUB, a display layer DISL, and a touch sensor layer ISP. The display layer DISL may include a thin film transistor layer TFTL, a light emitting element layer EML, and an encapsulation layer TFEL.

The substrate SUB may be made of an insulating material, such as a polymer resin. For example, the substrate SUB may be made of polyimide. The substrate SUB may be a flexible substrate capable of being subjected to bending, folding, and rolling.

The thin film transistor layer TFTL may be disposed on the substrate SUB. The thin film transistor layer TFTL may include a barrier film BR, a thin film transistor TFT1, a first capacitor electrode CAE1, a second capacitor electrode CAE2, a first anode connection electrode ANDE1, a second anode connection electrode ANDE2, a gate insulating film 130, a first interlayer insulating film 141, a second interlayer insulating film 142, a first planarization film 160, and a second planarization film 180.

The barrier film BR may be disposed on the substrate SUB. The barrier film BR is a film for protecting the thin film transistors of the thin film transistor layer TFTL and the light emitting layer 172 of the light emitting element layer EML from moisture permeated through the substrate SUB vulnerable to moisture permeation. The barrier film BR may be formed of a plurality of inorganic films that are alternately stacked. For example, the barrier film BR may be formed as a multi-film in which one or more inorganic films of a silicon nitride layer, a silicon oxynitride layer, a silicon oxide layer, a titanium oxide layer, and/or an aluminum oxide layer are alternately stacked.

The thin film transistor TFT1 may be disposed on the barrier film BR. An active layer ACT1 of the thin film transistor TFT1 may be disposed on the barrier film BR. The active layer ACT1 of the thin film transistor TFT1 may include polycrystalline silicon, single crystal silicon, low-temperature polycrystalline silicon, amorphous silicon, or oxide semiconductor.

The active layer ACT1 may include a channel area CHA1, a source area TS1 and a drain area TD1. The channel area CHA1 may be an area that overlaps with a gate electrode TG1 in the third direction DR3 that is the thickness direction of the substrate SUB. The source area TS1 may be disposed on one side of the channel area CHA1, and the drain area TD1 may be disposed on another side of the channel area CHA1. The source area TS1 and the drain area TD1 may be areas that do not overlap with the gate electrode TG1 in the third direction DR3. The source area TS1 and the drain area TD1 may be areas having conductivity by doping a silicon semiconductor or an oxide semiconductor with ions or impurities.

The gate insulating film 130 may be disposed on the active layer ACT1 of the thin film transistor TFT1. The gate insulating film 130 may be formed of an inorganic film, for example, a silicon nitride layer, a silicon oxynitride layer, a silicon oxide layer, a titanium oxide layer, or an aluminum oxide layer.

The gate electrode TG1 and the first capacitor electrode CAE1 of the thin film transistor TFT1 may be disposed on the gate insulating film 130. The gate electrode TG1 may overlap with the channel area CHA1 in the third direction DR3. Although FIG. 7 shows that the gate electrode TG1 and the first capacitor electrode CAE1 are disposed to be spaced apart from each other, the gate electrode TG1 and the first capacitor electrode CAE1 may be connected to each other to be integrally formed. The gate electrode TG1 and the first capacitor electrode CAE1 may be formed as a single layer or multi-layer made of any one of molybdenum (Mo), aluminum (Al), chromium (Cr), gold (Au), titanium (Ti), nickel (Ni), neodymium (Nd), and copper (Cu), or their alloy.

The first interlayer insulating film 141 may be disposed on the gate electrode TG1 and the first capacitor electrode CAE1 of the thin film transistor TFT1. The first interlayer insulating film 141 may be formed of an inorganic film, for example, a silicon nitride layer, a silicon oxynitride layer, a silicon oxide layer, a titanium oxide layer, or an aluminum oxide layer. The first interlayer insulating film 141 may be formed of a plurality of inorganic films.

The second capacitor electrode CAE2 may be disposed on the first interlayer insulating film 141. The second capacitor electrode CAE2 may overlap with the first capacitor electrode CAE1 of the thin film transistor TFT1 in the third direction DR3. Also, when the gate electrode TG1 and the first capacitor electrode CAE1 are integrally formed, the second capacitor electrode CAE2 may overlap with the gate electrode TG1 in the third direction DR3. Because the first interlayer insulating film 141 has a dielectric constant (e.g., a set or predetermined dielectric constant), a capacitor may be formed by the first capacitor electrode CAE1, the second capacitor electrode CAE2, and the first interlayer insulating film 141 disposed therebetween. The second capacitor electrode CAE2 may be formed as a single layer or multi-layer made of any one of molybdenum (Mo), aluminum (Al), chromium (Cr), gold (Au), titanium (Ti), nickel (Ni), neodymium (Nd), and copper (Cu), or their alloys.

The second interlayer insulating film 142 may be disposed on the second capacitor electrode CAE2. The second interlayer insulating film 142 may be formed of an inorganic film, for example, a silicon nitride layer, a silicon oxynitride layer, a silicon oxide layer, a titanium oxide layer, or an aluminum oxide layer. The second interlayer insulating film 142 may be formed of a plurality of inorganic films.

The first interlayer insulating film 141 and the second interlayer insulating film 142 may be included in the interlayer insulating film 140.

The first anode connection electrode ANDE1 may be disposed on the second interlayer insulating film 142. The first anode connection electrode ANDE1 may be connected to the drain area TD1 of the thin film transistor TFT1 through a first connection contact hole ANCT1 passing through the gate insulating film 130, the first interlayer insulating film 141, and the second interlayer insulating film 142. The first anode connection electrode ANDE1 may be formed as a single layer or multi-layer made of any one of molybdenum (Mo), aluminum (Al), chromium (Cr), gold (Au), titanium (Ti), nickel (Ni), neodymium (Nd), and copper (Cu), or their alloys.

The first planarization film 160 for planarizing a step difference due to the thin film transistor TFT1 may be disposed on the first anode connection electrode ANDE1. The first planarization film 160 may be formed of an organic film, such as an acrylic resin, an epoxy resin, a phenolic resin, a polyamide resin, a polyimide resin, and/or the like.

The second anode connection electrode ANDE2 may be disposed on the first planarization film 160. The second anode connection electrode ANDE2 may be connected to the first anode connection electrode ANDE1 through a second connection contact hole ANCT2 passing through the first planarization film 160. The second anode connection electrode ANDE2 may be formed as a single layer or multi-layer made of any one of molybdenum (Mo), aluminum (Al), chromium (Cr), gold (Au), titanium (Ti), nickel (Ni), neodymium (Nd), copper (Cu), or their alloys.

The second planarization film 180 may be disposed on the second anode connection electrode ANDE2. The second planarization film 180 may be formed of an organic film, such as an acrylic resin, an epoxy resin, a phenolic resin, a polyamide resin, a polyimide resin, or the like.

The light emitting element layer EML including light emitting elements LEL and a bank 190 may be disposed on the second planarization film 180. Each of the light emitting elements LEL may include a pixel electrode 171, a light emitting layer 172, and a common electrode 173.

The pixel electrode 171 may be disposed on the second planarization film 180. The pixel electrode 171 may be connected to the second anode connection electrode ANDE2 through a third connection contact hole ANCT3 passing through the second planarization film 180.

In a top emission structure that emits light in a direction of the common electrode 173 with respect to the light emitting layer 172, the pixel electrode 171 may be formed of a metal material having high reflectance, such as a stacked structure (Ti/Al/Ti) of aluminum and titanium, a stacked structure (ITO/Al/ITO) of aluminum and indium tin oxide (ITO), an APC alloy, or a stacked structure (ITO/APC/ITO) of APC alloy and ITO. The APC alloy may be an alloy of silver (Ag), palladium (Pd), and copper (Cu).

The bank 190 may be formed to partition the pixel electrode 171 on the second planarization film 180, thereby defining a first light emission area EA1 and a second light emission area EA2. The bank 190 may be disposed to cover an edge of the pixel electrode 171. The bank 190 may be formed of an organic film, such as an acrylic resin, an epoxy resin, a phenolic resin, a polyamide resin, and a polyimide resin.

Each of the first light emission area EA1 and the second light emission area EA2 represents an area in which the pixel electrode 171, the light emitting layer 172, and the common electrode 173 are sequentially stacked to recombine holes from the pixel electrode 171 with electrons from the common electrode 173 in the light emitting layer 172, thereby emitting light.

The light emitting layer 172 may be disposed on the pixel electrode 171 and the bank 190. The light emitting layer 172 may include an organic material to emit light of a set (e.g., predetermined) color. For example, the light emitting layer 172 may include a hole transporting layer, an organic material layer, and an electron transporting layer.

The common electrode 173 may be disposed on the light emitting layer 172. The common electrode 173 may be disposed to cover the light emitting layer 172. The common electrode 173 may be a common layer commonly formed in the first light emission area EA1 and the second light emission area EA2.

In the top emission structure, the common electrode 173 may be formed of a transparent conductive material (TCO), such as indium tin oxide (ITO) or indium zinc oxide (IZO), which may transmit light, or a semi-transmissive conductive material, such as magnesium (Mg), silver (Ag), or an alloy of magnesium (Mg) and silver (Ag). When the common electrode 173 is formed of a semi-transmissive metal material, light emission efficiency may be increased by a micro cavity.

A spacer 191 may be disposed on the bank 190. The spacer 191 may serve to support a mask during a manufacturing process of manufacturing the light emitting layer 172. The spacer 191 may be formed of an organic film, such as an acrylic resin, an epoxy resin, a phenolic resin, a polyamide resin, a polyimide resin, a polyimide resin, or the like.

In some embodiments, the display panel 400 may further include a capping layer CPL disposed on the common electrode 173. The capping layer CPL may include an inorganic material. For example, the capping layer CPL may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride.

The encapsulation layer TFEL may be disposed on the common electrode 173. The encapsulation layer TFEL may include at least one inorganic film to prevent oxygen or moisture from being permeated into the light emitting element layer EML. Also, the encapsulation layer TFEL may include at least one organic film to protect the light emitting element layer EML from particles, such as dust. For example, the encapsulation layer TFEL may include a first encapsulation inorganic layer TFE1, an encapsulation organic layer TFE2 and a second encapsulation inorganic layer TFE3.

The first encapsulation inorganic layer TFE1 may be disposed on the common electrode 173, the encapsulation organic layer TFE2 may be disposed on the first encapsulation inorganic layer TFE1, and the second encapsulation inorganic layer TFE3 may be disposed on the encapsulation organic layer TFE2. The first encapsulation inorganic layer TFE1 and the second encapsulation inorganic layer TFE3 may be formed as a multi-layer in which one or more inorganic films of a silicon nitride layer, a silicon oxynitride layer, a silicon oxide layer, a titanium oxide layer, and an aluminum oxide layer are alternately stacked. The encapsulation organic layer TFE2 may be an organic film, such as an acrylic resin, an epoxy resin, a phenolic resin, a polyamide resin, a polyimide resin, or the like.

The touch sensor layer ISP may be disposed on the encapsulation layer TFEL. The touch sensor layer ISP may be packaged in the display panel 400 through a continuous process. The touch sensor layer ISP may include a first touch insulating film TINS1, a first conductive layer ICL1, a second touch insulating film TINS2, a second conductive layer ICL2, and a third touch insulating film TINS3.

The first touch insulating film TINS1 may be disposed on the encapsulation layer TFEL. The first touch insulating film TINS1 may be formed of an inorganic film, for example, a silicon nitride layer, a silicon oxynitride layer, a silicon oxide layer, a titanium oxide layer, or an aluminum oxide layer.

The first conductive layer ICL1 may be disposed on the first touch insulating film TINS1. The first conductive layer ICL1 may be formed as a single layer or multi-layer made of any one of molybdenum (Mo), aluminum (Al), chromium (Cr), gold (Au), titanium (Ti), nickel (Ni), neodymium (Nd), copper (Cu), or their alloys.

The second touch insulating film TINS2 may be disposed on the first conductive layer ICL1. The second touch insulating film TINS2 may be formed of an inorganic film, for example, a silicon nitride layer, a silicon oxynitride layer, a silicon oxide layer, a titanium oxide layer, an aluminum oxide layer, or the like. For example, the second touch insulating film TINS2 may be formed of an organic film, such as an acrylic resin, an epoxy resin, a phenolic resin, a polyamide resin, a polyimide resin, or the like.

The second conductive layer ICL2 may be disposed on the second touch insulating film TINS2. The second conductive layer ICL2 may be formed as a single layer or multi-layer made of any one of molybdenum (Mo), aluminum (Al), chromium (Cr), gold (Au), titanium (Ti), nickel (Ni), neodymium (Nd), copper (Cu), or their alloys.

The third touch insulating film TINS3 may be formed on the second conductive layer ICL2. The third touch insulating film TINS3 may serve to planarize a step difference formed by the electrodes of the second conductive layer ICL2. The third touch insulating film TINS3 may be formed of an organic film, such as an acrylic resin, an epoxy resin, a phenolic resin, a polyamide resin, a polyimide resin, or the like.

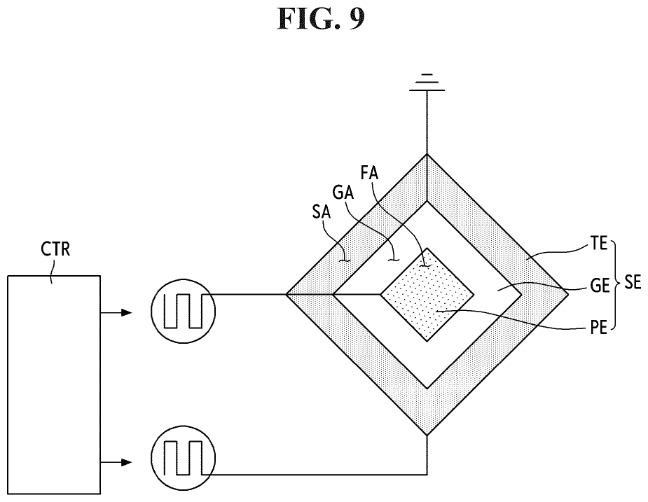

FIG. 8 is a plan view of an input sensor according to some embodiments of the present disclosure. FIG. 9 is a view illustrating a sensing electrode according to some embodiments of the present disclosure.

Referring to FIGS. 8 and 9, the touch sensor layer ISP of the display device 10 according to the present embodiment may include a digitizer. For example, a digitizer function may be embedded in the touch sensor layer ISP. For example, the touch sensor layer ISP may not only recognize an input by a user's touch (e.g., an input by a touch using a portion of a body) but also recognize an input of an input device, such as a pen (e.g., an input using an electromagnetic interaction) due to the digitizer embedded therein.

The touch sensor layer ISP may include a plurality of sensing electrodes SE. The plurality of sensing electrodes SE may be disposed in the display area DA. The touch sensor layer ISP may include touch pads TPD and a plurality of signal lines SL1, SL2, SL3, SL4, SL5, and SL6. The touch pads TPD and the plurality of signal lines SL1, SL2, SL3, SL4, SL5, and SL6 may be disposed in the non-display area NDA.

The plurality of sensing electrodes SE may include a first sensing electrode SE1 and a second sensing electrode SE2. The first sensing electrode SE1 may be provided as a plurality of first sensing electrodes SE1 to be arranged in the first direction DR1. The plurality of first sensing electrodes SE1 may be electrically connected to each other. The second sensing electrode SE2 may be provided as a plurality of second sensing electrodes SE2 to be arranged in the second direction DR2 crossing the first direction DR1. The plurality of second sensing electrodes SE2 may be electrically connected to each other. The first sensing electrode SE1 and the second sensing electrode SE2 may be electrically insulated from each other.

Each of the plurality of sensing electrodes SE may include a pen electrode PE and a touch electrode TE. The pen electrode PE may be an electrode that senses an input of an input device such as a pen. The touch electrode TE may be an electrode that senses a user's touch.

As shown in FIG. 9, the pen electrode PE may be disposed in a first area FA defined in each of the sensing electrodes SE, and the touch electrode TE may be disposed a second area SA. The first area FA may be surrounded by the second area SA. The first area FA may be a closed area surrounded by the second area SA.

A third area GA may be disposed between the first area FA and the second area SA. Sizes of the first area FA, the second area SA, and the third area GA are not limited to those shown in the drawing, and may be different from one another. The third area GA may be disposed between the first area FA and the second area SA. The third area GA may space the first area FA and the second area SA apart from each other.

Each of the plurality of sensing electrodes SE may further include a ground electrode GE. The ground electrode GE may be disposed in the third area GA. The ground electrode GE may be electrically grounded. The ground electrode GE may be disposed between the pen electrode PE and the touch electrode TE, so that signal interference between a signal of the pen electrode PE and a signal of the touch electrode TE may be reduced. In some embodiments, each of the plurality of sensing electrodes SE may include a separate insulating film for insulating the pen electrode PE and the touch electrode TE from each other, instead of the ground electrode GE.

As shown in FIG. 8, each of the plurality of first sensing electrodes SE1 may include a first pen electrode PE1, a first ground electrode GE1, and a first touch electrode TE1, and each of the plurality of second sensing electrodes SE2 may include a second pen electrode PE2, a second ground electrode GE2, and a second touch electrode TE2.

The touch sensor layer ISP may include a plurality of bridge electrodes for connecting the plurality of sensing electrodes SE. The bridge electrode may include pen bridge electrodes PBE1 and PBE2 for connecting adjacent pen electrodes PE among a plurality of pen electrodes PE, touch bridge electrodes TBE1 and TBE2 for connecting adjacent touch electrodes TE among a plurality of touch electrodes TE, and ground bridge electrodes GBE1 and GBE2 for connecting adjacent ground electrodes GE among a plurality of ground electrodes GE.

The pen bridge electrode may include a first pen bridge electrode PBE1 for connecting adjacent first pen electrodes PE1 among a plurality of first pen electrodes PE1, and a second pen bridge electrode PBE2 for connecting adjacent second pen electrodes PE2 among a plurality of second pen electrodes PE2.

The touch bridge electrode may include a first touch bridge electrode TBE1 for connecting adjacent first touch electrodes TE1 among a plurality of first touch electrodes TE1 and a second touch bridge electrode TBE2 for connecting adjacent second touch electrodes TE2 among a plurality of second touch electrodes TE2.

The ground bridge electrodes GBE1 and GBE2 may include a first ground bridge electrode GBE1 for connecting adjacent first ground electrodes GE1 among a plurality of first ground electrodes GE1, and a second ground bridge electrode GBE2 for connecting adjacent second ground electrodes GE2 among a plurality of second ground electrodes GE2.

The first pen bridge electrode PBE1, the first touch bridge electrode TBE1, and the first ground bridge electrode GBE1 may be disposed on different layers from the second pen bridge electrode PBE2, the second touch bridge electrode TBE2, and the second ground bridge electrode GBE2.

The plurality of signal lines SL1, SL2, SL3, SL4, SL5, and SL6 may electrically connect the plurality of sensing electrodes SE with the sensor controller CTR through the touch pads TPD, or may be grounded.

For example, the first signal line SL1 may connect the first touch electrode TE1 with the sensor controller CTR through the touch pad TPD. The second signal line SL2 may connect the second touch electrode TE2 with the sensor controller CTR through the touch pad TPD. The third signal line SL3 may connect the first pen electrode PE1 with the sensor controller CTR through the touch pad TPD. The fourth signal line SL4 may connect the second pen electrode PE2 with the sensor controller CTR through the touch pad TPD. The fifth signal line SL5 may be connected to the first ground electrode GE1. The sixth signal line SL6 may be connected to the second ground electrode GE2.

The sensor controller CTR may be included in the display device 10 separately from the touch sensor layer ISP. For example, the sensor controller CTR may be packaged on the display panel 400 of the display device 10 in the form of a driving chip.

The sensor controller CTR may be a control device that controls driving of the touch sensor layer ISP. The sensor controller CTR may drive the touch sensor layer ISP to simultaneously sense an input by a user's touch and an input of an input device.

For example, the sensor controller CTR may transmit an uplink signal to the input device and receive a downlink signal from the input device in order to sense the input of the input device. The uplink signal may be a signal provided by the sensor controller CTR to the input device in order to sense an approach of the input device. The downlink signal may be a signal provided by the input device to the sensor controller CTR in order to provide pen data, position information of the input device, and data on slope and state information of the input device. In addition, the sensor controller CTR may apply a voltage to the sensing electrodes SE (see FIG. 8) and sense a change in capacitance of the sensing electrodes SE (see FIG. 8) in order to sense the input by the user's touch.

In some embodiments, as shown in FIG. 9, signals having different phases may be applied to the touch electrode TE and the pen electrode PE from the sensor controller CTR. A positive phase signal may be applied to the touch electrode TE as a sensing signal, and an inverse phase signal may be applied to the pen electrode PE as a compensation signal. The inverse phase signal of the touch electrode TE may compensate for the positive phase signal of the pen electrode PE. The inverse phase signal of the touch electrode TE may reduce noise between the touch electrode TE and the pen electrode PE, which occurs while an uplink signal of a positive phase of the pen electrode PE is provided to the input device. The ground electrode GE may be separated from the touch electrode TE and the pen electrode PE, and a ground signal may be applied thereto.

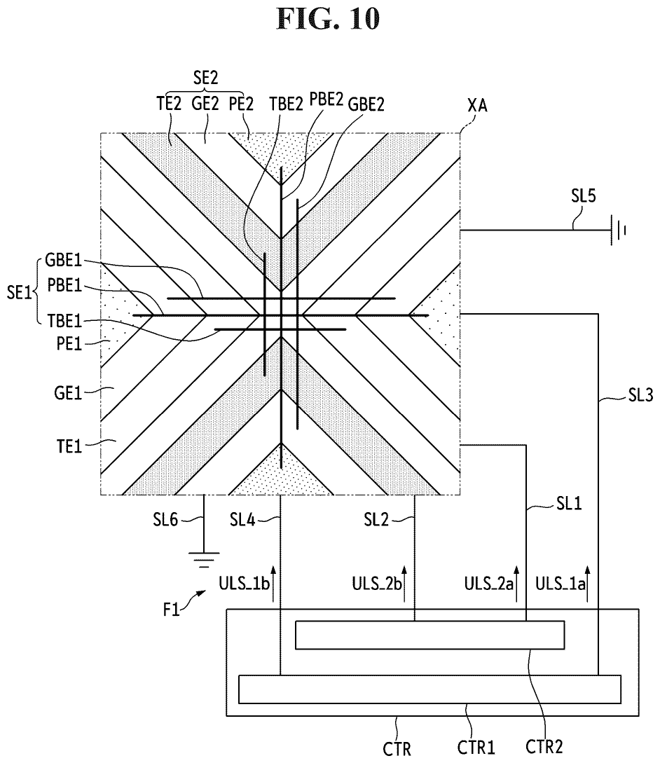

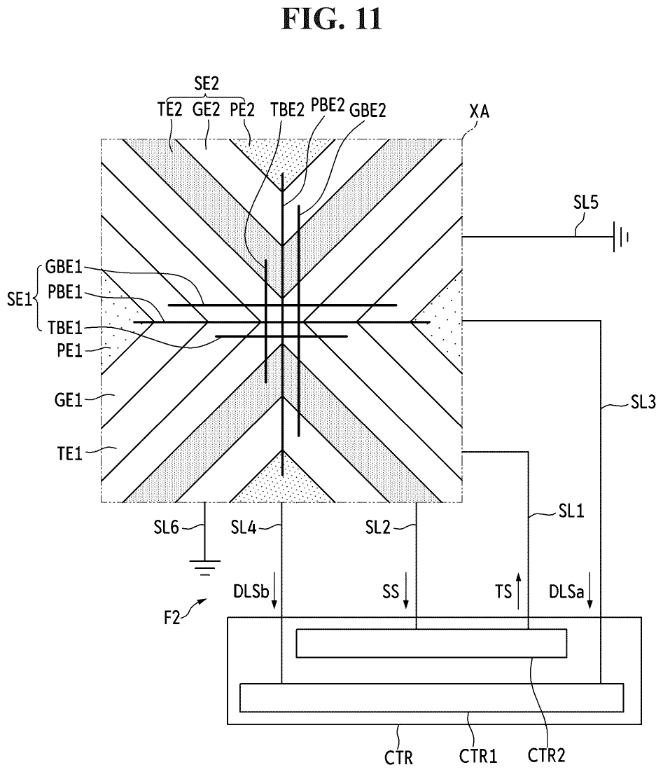

FIG. 10 is a view illustrating an operation of a display device according to some embodiments of the present disclosure of the present disclosure in a first frame. FIG. 11 is a view illustrating an operation of a display device according to some embodiments of the present disclosure of the present disclosure in a second frame.

Referring to FIGS. 10 and 11 in addition to FIGS. 8 and 9, the display device 10 may recognize the input of the input device during a first frame F1 and sense the input of the input device and the input by the user's touch during a second frame F2. The sensor controller CTR may be connected to the plurality of sensing electrodes SE of the touch sensor layer ISP to sense the input by the user's touch and the input of the input device.

As shown in FIG. 10, the sensor controller CTR may apply uplink signals ULS_1a, ULS_1b, ULS_2a, and ULS_2b to the plurality of sensing electrodes SE during the first frame F1. The plurality of sensing electrodes SE may recognize the input device approaching the touch sensor layer ISP through the uplink signals ULS_1a, ULS_1b, ULS_2a, and ULS_2b. When the input device is recognized, the touch sensor layer ISP and the input device may be synchronized or paired.

As shown in FIG. 11, when the touch sensor layer ISP is paired with the input device, the input device may apply downlink signals DLSa and DLSb to the sensor controller CTR through the plurality of sensing electrodes SE during the second frame F2. The sensor controller CTR may sense the input of the input device based on the downlink signals DLSa and DLSb.

The uplink signals ULS_1a, ULS_1b, ULS_2a, and ULS_2b may include first signals ULS_1a and ULS_1b and second signals ULS_2a and ULS_2b. The first signals ULS_1a and ULS_1b may be applied to the pen electrode PE, and the second signals ULS_2a and ULS_2b may be applied to the touch electrode TE.

The sensor controller CTR may apply the first signals ULS_1a and ULS_1b to the first pen electrode PE1 and the second pen electrode PE2, respectively. The sensor controller CTR may apply the second signals ULS_2a and ULS_2b to the first touch electrode TE1 and the second touch electrode TE2, respectively.

The first signals ULS_1a and ULS_1b may be uplink signals provided to the input device. The second signals ULS_2a and ULS_2b may be compensation signals for reducing noise generated between the touch electrode TE and the pen electrode PE in a communication process between the first signals ULS_1a and ULS_1b and the input device. The second signals ULS_2a and ULS_2b may be inverse phase signals of the first signals ULS_1a and ULS_1b. For example, the first signals ULS_1a and ULS_1b and the second signals ULS_2a and ULS_2b may have inverse phases.

As shown in FIG. 11, the sensor controller CTR may sense the input by the user's touch through the plurality of sensing electrodes SE. The sensor controller CTR may sense an external input by sensing the amount of a change in mutual capacitance formed between the first touch electrode TE1 and the second touch electrode TE2.

The sensor controller CTR may provide a driving signal TS to the first touch electrode TE1 during the second frame F2. The sensor controller CTR may receive a sensing signal RS from the second touch electrode TE2. Therefore, the sensor controller CTR may compare the driving signal TS with the sensing signal RS corresponding thereto and sense the input by the user's touch based on the amount of a change in the driving signal TS and the sensing signal RS.

The sensor controller CTR may receive the downlink signals DLSa and DLSb from the input device through the first pen electrode PE1 and the second pen electrode PE2 during the second frame F2. The sensor controller CTR may determine coordinates of the input device based on the first downlink signal DLSa and the second downlink signal DLSb.

The sensor controller CTR may be connected to the pen electrode PE and the touch electrode TE, and may drive the pen electrode PE and the touch electrode TE independently of each other.

In some embodiments, as shown in FIGS. 10 and 11, the sensor controller CTR may include an input device controller CTR1 and a touch controller CTR2. The input device controller CTR1 and the touch controller CTR2 may be independently driven to drive the pen electrode PE and the touch electrode TE, respectively. The input device controller CTR1 may be connected to the pen electrode PE, and the touch controller CTR2 may be connected to the touch electrode TE.

The sensor controller CTR may simultaneously drive the pen electrode PE for sensing the input by the input device and the touch electrode TE for sensing the input by the user's touch during the second frame F2 by the input device controller CTR1 and the touch controller CTR2, which operate independently at different frequency bands. Therefore, high-speed driving of a frequency of about 240 HZ or higher is possible.

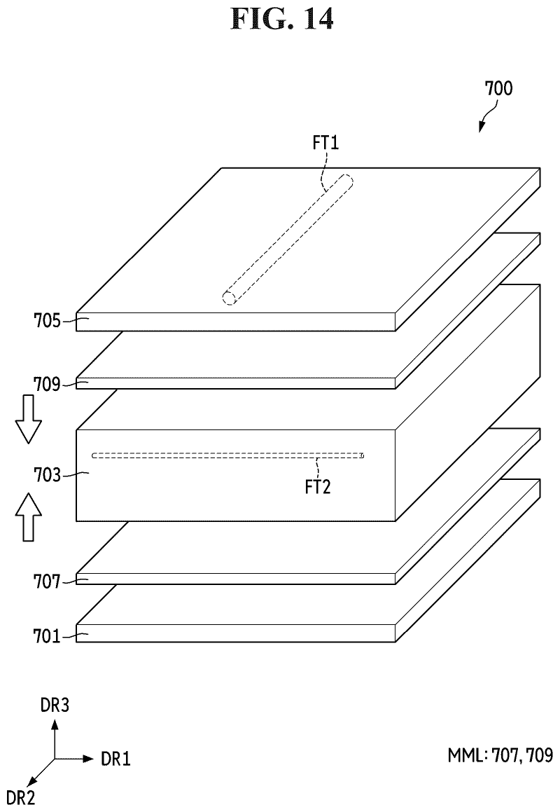

FIG. 12 is a cross-sectional view illustrating a panel support layer according to some embodiments of the present disclosure. FIG. 13 is a cross-sectional view illustrating a stacked structure of a panel support layer according to some embodiments of the present disclosure. FIG. 14 is a perspective view illustrating a panel support layer according to some embodiments of the present disclosure.

Referring to FIGS. 12 to 14, the panel support layer 700 may include a folding portion 710, a first non-folding portion 720 and a second non-folding portion 730. The folding portion 710 may be disposed in the folding area FDA, the first non-folding portion 720 may be disposed in the first non-folding area NFA1, and the second non-folding portion 730 may be disposed in the second non-folding area NFA2.

The first non-folding portion 720 and the second non-folding portion 730 may be portions that are non-folded (e.g., not folded) during folding of the display device 10. The first non-folding portion 720 may be disposed on the other side of the folding portion 710 in the first direction DR1, and the second non-folding portion 730 may be disposed on one side of the folding portion 710 in the first direction DR1.

The folding portion 710 may be a portion that is folded during folding of the display device 10. The folding portion 710 may be disposed between the first non-folding portion 720 and the second non-folding portion 730 in the first direction DR1.

The folding portion 710 may include a grid pattern. For example, the folding portion 710 may include a plurality of bars BAR and a plurality of slits SLT disposed between the plurality of bars BAR. The plurality of bars BAR are shown as having five bars, but is not limited thereto, and various modifications may be made in the number of bars in the plurality of bars BAR.

The plurality of bars BAR may include a first bar BAR1, a second bar BAR2, and a third bar BAR3. The first bar BAR1 may be positioned approximately at a center of the folding area FDA. The second bar BAR2 may be disposed on each of one side and another side of the first bar BAR1. The third bar BAR3 may be disposed on each of one side and another side of the second bar BAR2.

In some embodiments, the panel support layer 700 of the display device 10 according to the present embodiment may include an active control pattern as the grid pattern. In the active control pattern, a width of the plurality of bars BAR may become narrower from the center of the folding portion 710 toward edges thereof, for example, portions adjacent to the first and second non-folding portions 720 and 730.

For example, a width W1 of the first bar BAR1 may be greater than a width W2 of the adjacent second bar BAR2 adjacent thereto, and the width W2 of the second bar BAR2 may be greater than a width W3 of the third bar BAR3 adjacent thereto. Therefore, rigidity of the first bar BAR1 may be greater than rigidity of the second bar BAR2, and rigidity of the second bar BAR2 may be greater than rigidity of the third bar BAR3.

The panel support layer 700 of the display device 10 according to the present embodiment may include an active control pattern, thereby reducing stress applied to the folding area FDA during folding of the display device 10 and minimizing or substantially reducing the likelihood of a crease forming in the folding area FDA.

In detail, folding stress applied to a central portion of the folding portion 710 having the largest rotation radius during folding of the display device 10 may be greater than folding stress applied to the edge of the folding portion 710.

Because the width W1 of the first bar BAR1 is the largest in the active control pattern, rigidity of the first bar BAR1 is the largest (e.g., greatest), so that folding stress applied to the central portion of the folding portion 710 may be reduced.

The panel support layer 700 may be a fiber-reinforced plastic containing a fiber yarn and a base resin RS. The fiber yarn may be dispersed in the base resin RS. The fiber yarn may include graphene as a carbon fiber containing carbon, and the base resin RS may be an epoxy resin, a polyester resin, a polyamide resin, a polycarbonate resin, a polypropylene resin, a polybutylene resin, a polyacrylate resin, a vinyl ester resin, or the like.

The panel support layer 700 may include a first layer 701, a second layer 703 disposed on the first layer 701, and a third layer 705 disposed on the second layer 703.

The base resin RS may be disposed in each of the first layer 701, the second layer 703, and the third layer 705. A portion of the base resin RS disposed in the first layer 701 may be referred to as a first base resin, a portion of the base resin RS disposed in the second layer 703 may be referred to as a second base resin, and a portion of the base resin RS disposed in the third layer 705 may be referred to as a third base resin.

The fiber yarn may be made of a carbon fiber, and may have a cylindrical shape having a circular cross-section. The fiber yarn may include a first fiber yarn FT1 and a second fiber yarn FT2, which have different diameters, different modulus of elasticity, and/or different carbon contents. The first fiber yarn FT1 may be disposed on the first layer 701 and the third layer 705 of the panel support layer 700, and the second fiber yarn FT2 may be disposed on the second layer 703 of the panel support layer 700. For example, the same type of fiber yarn may be disposed on the first layer 701 and the third layer 705 as the first fiber yarn FT1, and a different type of fiber yarn from the fiber yarn disposed on the first layer 701 and the third layer 705 may be disposed on the second layer 703 as the second fiber yarn FT2.

For example, the first layer 701 may be a prepreg consisting of first fiber yarns FT1 extended generally in parallel in the second direction DR2 and a portion of the base resin RS surrounding the first fiber yarns FT1. The second layer 703 may be a prepreg consisting of second fiber yarns FT2 extended generally in parallel in in the first direction DR1 and a portion of the base resin RS surrounding the second fiber yarns FT2. The third layer 705 may be a prepreg consisting of first fiber yarns FT1 extended generally in parallel in the second direction DR2 and a portion of the base resin RS surrounding the first fiber yarns FT1.

In the present disclosure, the meaning of “extended generally in parallel in the first direction DR1” may include a case of being completely parallel with the first direction DR1 or extended to form a pier of approximately 15° or less while slightly crossing the second direction DR2, and the meaning of “extended generally in parallel in the second direction DR2” may include a case of being completely parallel with the first direction DR1 or extended to form a pier of approximately 15° or less while slightly crossing the first direction DR1.

Because the first fiber yarn FT1 disposed on the first layer 701 and the third layer 705 is extended generally in parallel in the second direction DR2, and the second direction DR2 is a direction parallel with the folding lines FL1 and FL2 shown in FIGS. 1 and 2, the first layer 701 and the third layer 705 may be easily folded when the display device 10 is switched from the first state to the second state. However, when the panel support layer 700 includes only the first fiber yarn FT1, the panel support layer 700 may be bent or curved in the first direction DR1. That is, when the panel support layer 700 includes only the first fiber yarn FT1, flatness and rigidity of the panel support layer 700 may be relatively low.

Therefore, the panel support layer 700 may further include a second layer 703 having a second fiber yarn FT2 that is extended generally in the first direction DR1, thereby preventing or substantially reducing the likelihood of the panel support layer 700 being bent or curved in the first direction DR1 and increasing rigidity of the panel support layer 700.

In some embodiments, in consideration of the desired rigidity for the panel support layer 700, the content of the second fiber yarn FT2 of the panel support layer 700 may be greater than the content of the first fiber yarn FT1. For example, a width of the second layer 703 of the panel support layer 700 in the third direction DR3 may be greater than a width of the first layer 701 in the third direction DR3 and a width of the third layer 705 in the third direction DR3. The width of the first layer 701 in the third direction DR3 may be the same or substantially the same as the width of the third layer 705 in the third direction DR3, but is not limited thereto. In some embodiments, a thickness of the first layer 701 and a thickness of the third layer 705 may be 20 μm, approximately, and a thickness of the second layer 703 may be 100 μm, approximately, but is not limited thereto.

As described above, the fiber yarn extended in one direction may be disposed on each layer, so that the thickness of each layer itself may not increase. For example, when both the first fiber yarn FT1 and the second fiber yarn FT2 are disposed on any one layer of the panel support layer 700, a portion where the first fiber yarn FT1 and the second fiber yarn FT2 cross each other may occur, and thus the thickness of the layer itself may be increased. Therefore, the fiber yarn extended in only one direction may be disposed on each layer to ensure suitable rigidity for the panel support layer 700 while not increasing the thickness of the layer itself.

The panel support layer 700 may further include a lower functional layer MML. The lower functional layer MML may perform a heat dissipation function and an electromagnetic wave shielding function. The lower functional layer MML may include a metal film, such as copper, nickel, ferrite or silver, which has suitable thermal conductivity. The lower functional layer MML may include a magnetic metal powder (MMP) containing magnetic particles, as an electromagnetic wave absorber.

In some embodiments, the lower functional layer MML may include a first functional layer 707 and a second functional layer 709. The first functional layer 707 may be disposed between the first layer 701 and the second layer 703. The second functional layer 709 may be disposed between the second layer 703 and the third layer 705.

In the display device 10 according to some embodiments, the lower functional layer MML may be packaged in the panel support layer 700, so that the thickness of the display device 10 may be reduced. For example, because the lower functional layer MML may be packaged in the panel support layer 700 without being separately provided below the panel support layer 700, a distance from the display panel 400 may be reduced so that a heat dissipation function and an electromagnetic wave shielding function may be further improved. Therefore, the thickness of the lower functional layer MML may be reduced, so that the thickness of the display device 10 may be reduced. In addition, the process may be simplified and the cost may be reduced as compared with a process of attaching a module including a separate lower functional layer MML, such as forming the lower functional layer MML in the process of manufacturing the panel support layer 700.

Hereinafter, other examples of a display device according to some embodiments will be described. In the following embodiments, the same reference numerals will be given to the same elements as those of the previous embodiments, a redundant description of the previous embodiments will be omitted or simplified, and the description will be based on differences from the previous embodiments.

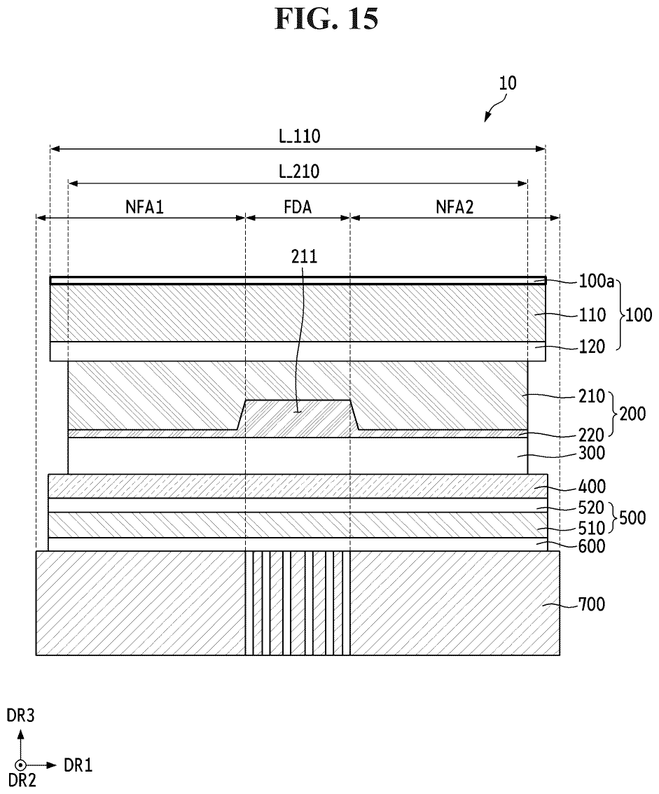

FIG. 15 is a cross-sectional view illustrating a display device according to some other embodiments of the present disclosure.

Referring to FIG. 15 in addition to FIGS. 5 and 6, the display device 10 according to the present embodiment is different from the display device 10 according to some embodiments of the present disclosure described with reference to FIG. 5 in the order of stacking the window 210 and the resin 220 of the window composite layer 200.

In more detail, the window 210 may be disposed on the resin 220. For example, the window 210 may be disposed on an upper portion of the resin 220. The window 210 may be disposed between the resin 220 and the upper protective film 100, and the resin 220 may be disposed between the window 210 and the second adhesive layer 300. For example, the display device 10 according to some embodiments is different from the display device 10 according to the embodiments described with reference to FIG. 5 in that the up and down arrangement of the window composite layer 200 is inverted.

Therefore, a shape of the groove 211 may be inverted in comparison with the display device 10 according to the embodiments described with reference to FIG. 5. For example, the groove 211 may be a portion in which one surface (e.g., a lower surface) of the window 210 is recessed toward the other surface (e.g., an upper surface) of the window 210. The base surface 210a of the window 210 may be positioned to be higher than the top surface 210c.

Because the resin 220 as shown in FIG. 15 is disposed below the window 210, a length L_210 (or a size) of the window 210 may be smaller than or equal to a length L_110 (or a size) of the upper protective layer 110 to prevent the window 210 from being scattered to a user positioned toward (e.g., facing) a display surface (e.g., a surface where the coating film 100a is positioned) of the display device 10 beyond the upper protective film 100.

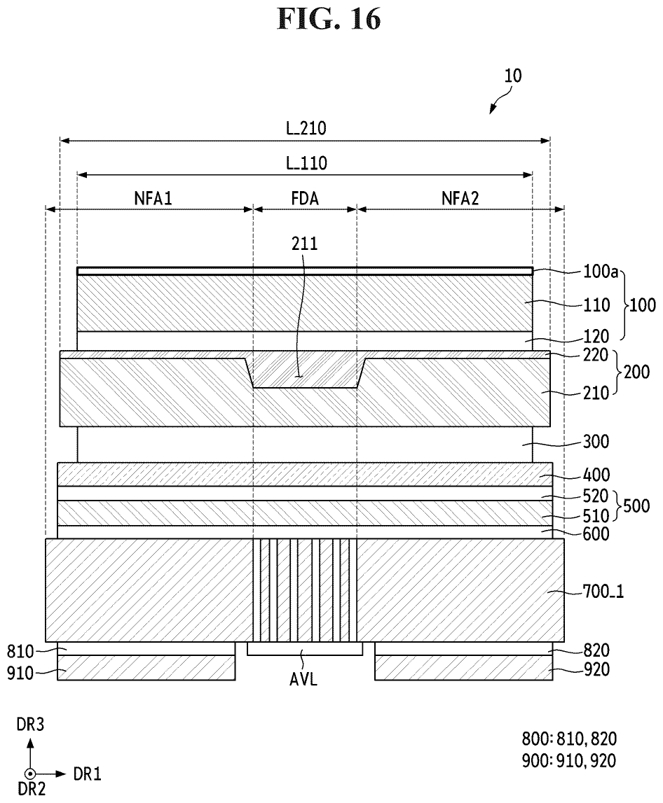

FIG. 16 is a cross-sectional view illustrating a display device according to some other embodiments of the present disclosure.

Referring to FIG. 16 in addition to FIG. 13, the display device 10 according to some embodiments is different from the display device 10 according to the embodiments described with reference to FIG. 5 in that it includes a fifth adhesive layer 800 and an independent lower functional layer 900 and a panel support layer 700_1 does not include a lower functional layer MML.

In more detail, the panel support layer 700_1 may not include (e.g., exclude or omit) the lower functional layer MML shown in FIG. 13. For example, the panel support layer 700_1 may not include the first functional layer 707 and the second functional layer 709. Therefore, the panel support layer 700_1 may have a structure in which the first layer 701, the second layer 703, and the third layer 705 are sequentially stacked.

The display device 10 may include a lower functional layer 900, which is separately independent, below the panel support layer 700_1. Because the lower functional layer 900 is substantially the same as the lower functional layer MML described with reference to FIG. 13, its description will be omitted.

In some embodiments, the lower functional layer 900 may include a first lower functional layer 910 and a second lower functional layer 920. The first lower functional layer 910 may be disposed in the first non-folding area NFA1, and the second lower functional layer 920 may be disposed in the second non-folding area NFA2. The lower functional layer 900 may not be disposed in the folding area FDA to improve the folding property of the display device 10.

The display device 10 may further include a fifth adhesive layer 800 and a lower anti-visible layer AVL disposed between the panel support layer 700_1 and the lower functional layer 900 in the third direction DR3.

The fifth adhesive layer 800 may be disposed on the lower functional layer 900. For example, the fifth adhesive layer 800 may be disposed between the panel support layer 700 and the lower functional layer 900. The panel support layer 700 and the lower functional layer 900 may be coupled to each other through the fifth adhesive layer 800. The fifth adhesive layer 800 may include a transparent adhesive such as a pressure sensitive adhesive (PSA) or an optically clear adhesive (OCA). For example, the fifth adhesive layer 800 may include an acrylic adhesive material.

The fifth adhesive layer 800 may include a first sub-adhesive layer 810 and a second sub-adhesive layer 820. The first sub-adhesive layer 810 may be disposed in the first non-folding area NFA1, and the second sub-adhesive layer 820 may be disposed in the second non-folding area NFA2. The fifth adhesive layer 800 may not be disposed in the folding area FDA to improve the folding property of the display device 10.

The lower anti-visible layer AVL may overlap with the grid pattern of the panel support layer 700_1. The lower anti-visible layer AVL may be disposed in the folding area FDA. For example, the lower anti-visible layer AVL may be disposed between the first sub-adhesive layer 810 and the second sub-adhesive layer 820. In some embodiments, a width of the lower anti-visible layer AVL may be greater than a width of the folding area FDA, and at least a portion of the lower anti-visible layer AVL may be also disposed in the non-folding areas NFA1 and NFA2.

The lower anti-visible layer AVL may allow the grid pattern of the panel support layer 700_1 not to be visible to the outside. The lower anti-visible layer AVL may include a material having flexibility to reduce folding stress of the display device 10, and may include a material having relatively low transmittance. For example, the lower anti-visible layer AVL may include thermoplastic polyurethane (TPU).

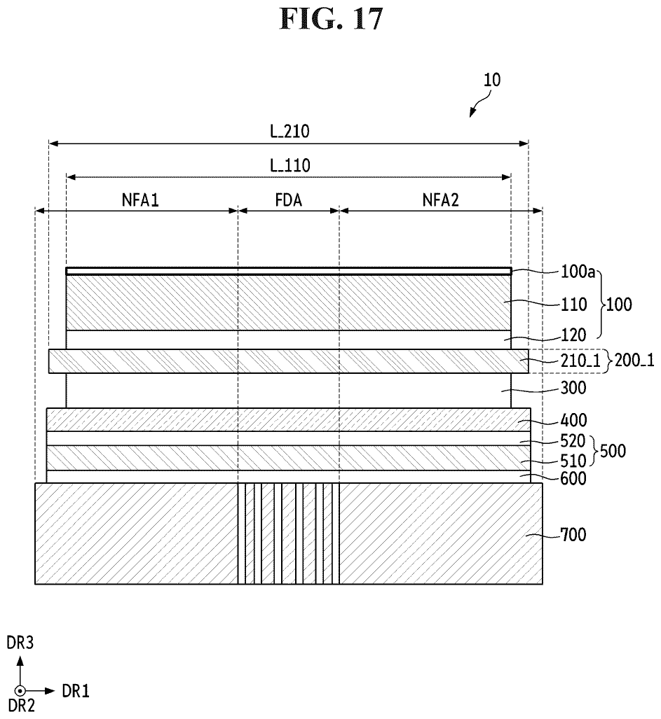

FIG. 17 is a cross-sectional view illustrating a display device according to some other embodiments of the present disclosure.

Referring to FIG. 17 in addition to FIG. 5, the display device 10 according to some embodiments is different from the display device 10 according to the embodiments described with reference to FIG. 5 in that a window composite layer 200_1 does not include a resin 220 and a window 210_1 does not include a groove 211.

In more detail, the window composite layer 200_1 may include the window 210_1. The window composite layer 200_1 may not include the resin 220 described with reference to FIG. 5. The window 210_1 may be in direct contact with the upper protective film 100 and the second adhesive layer 300. The window 210_1 may not include the groove 211 described with reference to FIG. 5. The window 210_1 may be an ultra-thin glass (UTG) having an approximately constant thickness, rather than a hybrid thin glass (HTG). The thickness of the window 210_1 may be approximately constant over the folding area FDA and the non-folding areas NFA1 and NFA2. For example, a cross-sectional shape of the window 210_1 may be an approximately rectangular shape.

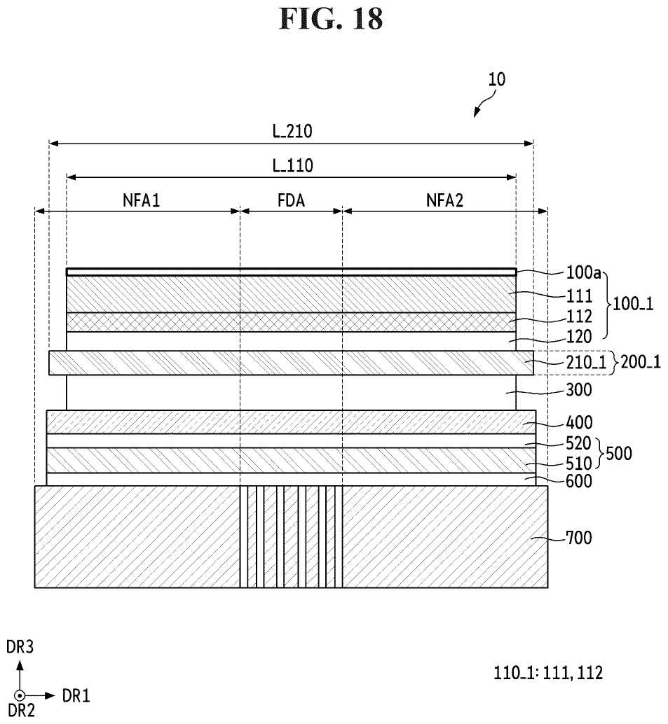

FIG. 18 is a cross-sectional view illustrating a display device according to some other embodiments of the present disclosure.

Referring to FIG. 18 in addition to FIGS. 5 and 17, the display device 10 according to some embodiments is different from the display device 10 according to the embodiments described with reference to FIG. 17 in that an upper protective layer 110_1 of an upper protective film 100_1 includes a first support layer 111 and a second support layer 112.

In more detail, a window composite layer 200_1 of the display device 10 according to some embodiments may be substantially the same as the window composite layer 200_1 of the display device 10 according to the embodiments of the present disclosure described with reference to FIG. 17.

Because the window composite layer 200_1 as shown in FIG. 18 does not include the resin 220, the display device 10 may further include a second support layer 112 as another element for reducing a repulsive force and enhancing impact resistance when the display device 10 is folded.

For example, the upper protective layer 110_1 of the upper protective film 100_1 may include a first support layer 111 and a second support layer 112. Because the first support layer 111 is substantially the same as the upper protective layer 110 of the display device 10 described with reference to FIG. 5, its description will be omitted.

The second support layer 112 may have a modulus of elasticity different from that of the first support layer 111. For example, the modulus of elasticity of the second support layer 112 may be smaller than that of the first support layer 111.

In some embodiments, when a thickness (a length in the third direction DR3) of the upper protective layer 110_1 of the display device 10 according to some embodiments is substantially the same as a thickness (a length in the third direction DR3) of the upper protective layer 110 of the display device 10 according to some embodiments described with reference to FIG. 5, a thickness (a length in the third direction DR3) of the first support layer 111 may be smaller than the thickness (the length in the third direction DR3) of the upper protective layer 110 of the display device 10 according to some embodiments described with reference to FIG. 5 as much as a thickness (a length in the third direction DR3) of the second support layer 112.

Therefore, even though the thickness of the upper protective layer 110_1 of the display device 10 according to the some embodiments as shown in FIG. 18 may be substantially the same as the thickness of the upper protective layer 110 of the display device 10 according to some embodiments described with reference to FIG. 5, the display device 10 according to the embodiments as shown in FIG. 18 includes the second support layer 112 having lower modulus of elasticity, thereby reducing a repulsive force and enhancing impact resistance when the display device 10 is folded.

In some embodiments, the second support layer 112 may be disposed below the first support layer 111, but is not limited thereto. The second support layer 112 may be disposed on the first support layer 111.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a display panel comprising a folding area and a non-folding area on one side of the folding area;
a window composite layer on one surface of the display panel, comprising a window and a resin on the window;
an upper protective film on the window composite layer; and
a panel support layer on another surface of the display panel, wherein:
the window comprises a first portion that overlaps with the folding area, and a second portion on one side of the first portion;
a thickness of the second portion is greater than a thickness of the first portion; and
a thickness of the resin on the first portion is greater than a thickness of the resin on the second portion.

2. The display device of claim 1, wherein the window comprises a first surface and a second surface positioned to be opposite to the first surface, and
wherein the window comprises a groove recessed toward the second surface on the first surface.

3. The display device of claim 2, wherein the first surface comprises a first sub-surface and a second sub-surface, which are positioned at different heights, and a third sub-surface positioned between the first sub-surface and the second sub-surface,
wherein the first sub-surface is positioned on a bottom surface of the groove,
wherein the second sub-surface is positioned at a portion of the first surface, in which the groove is not positioned, and
wherein the third sub-surface is positioned on an inner side of the groove.

4. The display device of claim 3, wherein each of the first sub-surface and the second sub-surface is a flat surface.

5. The display device of claim 3, wherein the third sub-surface is an inclined surface or a vertical surface.

6. The display device of claim 2, wherein the first surface faces the upper protective film, and the second surface faces the display panel.

7. The display device of claim 6, wherein the resin is between the upper protective film and the window.

8. The display device of claim 2, wherein the second surface faces the upper protective film, and the first surface faces the display panel.

9. The display device of claim 8, wherein the resin is between the display panel and the window.

10. The display device of claim 1, wherein the display panel comprises a light emitting element layer and a touch sensor layer on the light emitting element layer,
wherein the touch sensor layer comprises a plurality of first sensing electrodes and a plurality of second sensing electrodes, which are arranged in different directions and comprise a first electrode and a second electrode, respectively, and
wherein the second electrode surrounds the first electrode.

11. The display device of claim 10, wherein the touch sensor layer comprises a plurality of first bridge electrodes electrically connecting the plurality of first sensing electrodes to each other and a plurality of second bridge electrodes electrically connecting the plurality of second sensing electrodes to each other,
wherein the first bridge electrodes are insulated from the plurality of second sensing electrodes, and
wherein the second bridge electrodes are insulated from the plurality of first sensing electrodes.

12. The display device of claim 1, wherein the panel support layer comprises a grid pattern in the folding area, comprising a plurality of bars and a plurality of slits between the plurality of bars, and
wherein a width of the plurality of bars becomes narrower from a center toward an edge of the folding area.

13. The display device of claim 1, wherein the panel support layer comprises a lower functional layer comprising a magnetic metal powder.

14. The display device of claim 13, wherein the panel support layer comprises:
a first layer comprising a first fiber extending in a first direction;
a second layer on the first layer and containing a second fiber extending in a second direction different from the first direction; and
a third layer on the second layer and containing the first fiber, and
wherein the lower functional layer further comprises a first functional layer between the first layer and the second layer and a second functional layer between the second layer and the third layer.

15. The display device of claim 1, further comprising a lower functional layer on the panel support layer,
wherein the lower functional layer contains a magnetic metal powder.

16. A television comprising:
a display device of claim 1; and
a speaker configured to generate audio corresponding to images displayed on the display device.

17. A smart phone comprising:
a display device of claim 1; and
a battery configured to store electrical energy and to power the display device.

18. A display device comprising:
a display panel comprising a folding area and a non-folding area on one side of the folding area and further comprising a light emitting element layer and a touch sensor layer on the light emitting element layer, the touch sensor layer comprising a digitizer;
a window on one surface of the display panel, having a constant thickness;
an upper protective film on the window; and
a panel support layer on another surface of the display panel, and comprising a lower functional layer containing a magnetic metal powder.

19. The display device of claim 18, wherein the upper protective film comprises a first support layer and a second support layer on the first support layer, and
a modulus of elasticity of the second support layer is smaller than a modulus of elasticity of the first support layer.

20. The display device of claim 19, wherein the second support layer is below the first support layer.

21. The display device of claim 18, wherein the panel support layer comprises:
a first layer containing a first fiber extending in a first direction;
a second layer on the first layer and containing a second fiber extending in a second direction different from the first direction; and
a third layer on the second layer and containing the first fiber, and
wherein the lower functional layer further comprises a first functional layer between the first layer and the second layer and a second functional layer between the second layer and the third layer.

22. The display device of claim 18, wherein the touch sensor layer comprises a first sensing electrode for recognizing an input of an input device and a second sensing electrode for recognizing an input by a user's touch.
